(19) United States
(12) Patent Application Publication
(10) Pub. No.: US 2025/0380574 A1
(43) Pub. Date: Dec. 11, 2025

(54) DISPLAY DEVICE

(71) Applicant: Japan Display Inc., Tokyo (JP)

(72) Inventor: Tomohiko NAGANUMA, Tokyo (JP)

(73) Assignee: Japan Display Inc., Tokyo (JP)

(21) Appl. No.: 19/185,579

(22) Filed: Apr. 22, 2025

(30) Foreign Application Priority Data
Jun. 6, 2024 (JP) 2024-092258

(51) Int. Cl. H10K 59/122; H10K 59/80

(52) U.S. Cl. CPC H10K 59/122; H10K 59/873; H10K 59/879

(57) ABSTRACT

According to one embodiment, a display device includes a first lower electrode and a second lower electrode spaced apart from each other, a rib layer having a first pixel aperture overlapping the first lower electrode and a second pixel aperture overlapping the second lower electrode, a first sealing layer covering the first lower electrode, a second sealing layer covering the second lower electrode, a third sealing layer covering the first sealing layer and the second sealing layer, and a light-shielding layer overlapping the rib layer in plan view. A distance between the first lower electrode and the light-shielding layer is greater than a distance between the second lower electrode and the light-shielding layer.

### CROSS-REFERENCE TO RELATED APPLICATIONS

This application is based upon and claims the benefit of priority from Japanese Patent Application No. 2024-092258, filed Jun. 6, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display devices, a technique capable of improving display quality is required.

### BRIEF DESCRIPTION OF THE DRAWINGS

FIG. 1 is a view showing a configuration example of a display device according to the first embodiment.

FIG. 2 is a schematic plan view showing an example of layouts of subpixels.

FIG. 3 is a schematic cross-sectional view of the display device according to the first embodiment along line III-III of FIG. 2.

FIG. 4 is a view showing an example of layer structures applicable to display elements.

FIG. 5 shows an example of internal emission spectra of a light emitting layer.

FIG. 6 is a cross-sectional view in which a partition shown in FIG. 3 is enlarged.

FIG. 7 shows an example of emission spectra.

FIG. 8 is a diagram showing relationships among angles of subpixels and brightness of the respective subpixels.

FIG. 9 is a schematic cross-sectional view of a display device according to the second embodiment.

FIG. 10 is a cross-sectional view in which a partition shown in FIG. 9 is enlarged.

FIG. 11 is a schematic plan view of a display device according to the third embodiment.

FIG. 12 is a schematic cross-sectional view of the display device according to the third embodiment along line XII-XII of FIG. 11.

### DETAILED DESCRIPTION

In general, according to one embodiment, a display device includes a substrate, a first lower electrode and a second lower electrode provided above the substrate and spaced apart from each other, a rib layer having a first pixel aperture overlapping the first lower electrode and a second pixel aperture overlapping the second lower electrode, a first organic layer contacting the first lower electrode through the first pixel aperture, a second organic layer contacting the second lower electrode through the second pixel aperture, a first upper electrode provided on the first organic layer, a second upper electrode provided on the second organic layer, a first sealing layer covering the first upper electrode, a second sealing layer covering the second upper electrode, a third sealing layer covering the first sealing layer and the second sealing layer, a first color filter covering the first pixel aperture, a second color filter covering the second pixel aperture and having a color different from that of the first color filter, and a light-shielding layer, which has a first end portion contacting the first color filter and a second end portion contacting the second color filter and overlaps the rib layer in plan view. The first organic layer and the second organic layer are configured to emit light in colors different from each other. A distance between the first lower electrode and the first end portion in a thickness direction of the substrate is greater than a distance between the second lower electrode and the second end portion.

Embodiments can provide a display device capable of improving display quality.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X direction. A direction parallel to the Y-axis is referred to as a Y direction. A direction parallel to the Z-axis is referred to as a Z direction. When various elements are viewed parallel to the Z direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

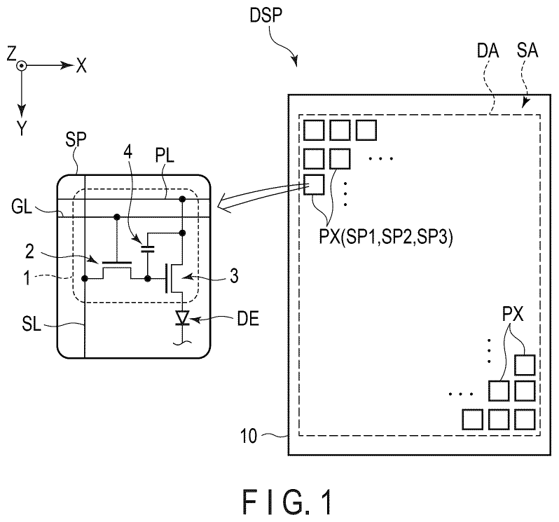

FIG. 1 is a view showing a configuration example of a display device DSP according to the first embodiment. The display device DSP comprises an insulating substrate 10. The substrate 10 has a display area DA displaying an image and a surrounding area SA around the display area DA. The substrate 10 may be glass or a resinous film having flexibility. The Z direction corresponds to the thickness direction of the substrate 10.

In the present embodiment, the shape of the substrate 10 is a rectangle in plan view. It should be noted that the shape of the substrate 10 in plan view is not limited to a rectangle and may be another shape such as a square, a circle or an oval.

The display area DA comprises a plurality of pixels PX arranged in a matrix in the X direction and the Y direction. Each pixel PX includes a plurality of subpixels SP that display different colors. The present embodiment assumes a case where each pixel PX includes a green subpixel SP1, a red subpixel SP2, and a blue subpixel SP3. However, each pixel PX may include a subpixel SP that exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines GL supplying the pixel circuit 1 of each subpixel SP with scanning signals, a plurality of signal lines SL supplying the pixel circuit 1 of each subpixel SP with video signals, and a plurality of power lines PL. In the example of FIG. 1, the scanning lines GL and the power lines PL extend in the X direction, and the signal lines SL extend in the Y direction.

A gate electrode of the pixel switch 2 is connected to the scanning line GL. A source electrode of the pixel switch 2 is connected to the signal line SL. A drain electrode of the pixel switch 2 is connected to the gate electrode of the drive transistor 3 and the capacitor 4. A source electrode of the drive transistor 3 is connected to the power line PL and the capacitor 4. The drain electrode of the drive transistor 3 is connected to the display element DE.

The configuration of the pixel circuit 1 is not limited to the example illustrated in the figure. For example, the pixel circuit 1 may comprise more thin-film transistors and capacitors.

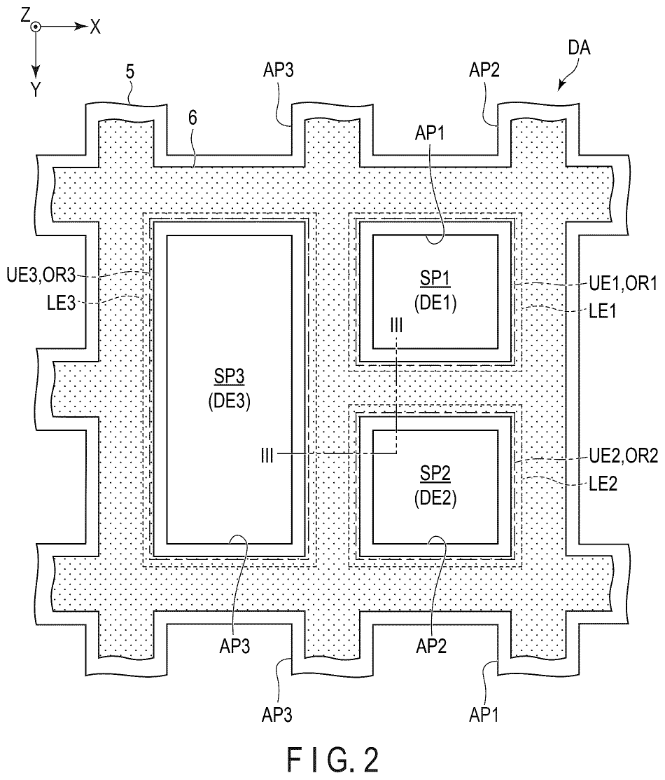

FIG. 2 is a schematic plan view showing an example of layouts of the subpixels SP1, SP2, and SP3. In the example of FIG. 2, the subpixels SP1 and SP2 are arranged with the subpixel SP3 in the X direction. Further, the subpixels SP1 and SP2 are arranged in the Y direction.

When the subpixels SP1, SP2 and SP3 are arranged in this layout, in the display area DA, a column in which the subpixels SP1 and SP2 are alternately arranged in the Y direction and a column in which the plurality of subpixels SP3 are repeatedly arranged in the Y direction are formed. These columns are alternately arranged in the X direction. The layout of the subpixels SP1, SP2, and SP3 is not limited to the example of FIG. 2.

A rib layer 5 is provided in the display area DA. The rib layer 5 has pixel apertures AP1, AP2, and AP3 (the first, second, and third pixel apertures) in the respective subpixels SP1, SP2, and SP3. In the example of FIG. 2, the pixel apertures AP1 and AP2 are rectangles of the same size in plan view. In contrast, the pixel aperture AP3 is a rectangle that is elongated in the Y direction more than the pixel apertures AP1 and AP2 are. The size and the shape of each of the pixel apertures AP1, AP2, and AP3 is not limited to this example.

The subpixel SP1 comprises a lower electrode LE1 (the first lower electrode), an upper electrode UE1 (the first upper electrode), and an organic layer OR1 (the first organic layer) that overlap the pixel aperture AP1. The subpixel SP2 comprises a lower electrode LE2 (the second lower electrode), an upper electrode UE2 (the second upper electrode), and an organic layer OR2 (the second organic layer) that overlap the pixel aperture AP2. The subpixel SP3 comprises a lower electrode LE3 (the third lower electrode), an upper electrode UE3 (the third upper electrode), and an organic layer OR3 (the third organic layer) that overlap the pixel aperture AP3.

Portions that overlap the pixel aperture AP1 of the lower electrode LE1, the upper electrode UE1, and the organic layer OR1 constitute a display element DE1 of the subpixel SP1. Portions that overlap the pixel aperture AP2 of the lower electrode LE2, the upper electrode UE2, and the organic layer OR2 constitute a display element DE2 of the subpixel SP2. Portions that overlap the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6 is provided in the display area DA. The partition 6 is located above the rib layer 5 to entirely overlap the rib layer 5. In the example of FIG. 2, the partition 6 has a planar shape equal to that of the rib layer 5. In other words, the partition 6 has an aperture in each of the subpixels SP1, SP2, and SP3. From another viewpoint, each of the rib layer 5 and the partition 6 has a grating shape in plan view and surrounds each of the display elements DE1, DE2, and DE3. The partition 6 functions as lines that supply the upper electrodes UE1, UE2, and UE3 with common voltage. The display device DSP according to the present embodiment comprises the partition 6. However, the display device DSP is not limited to this example and may not comprise the partition 6.

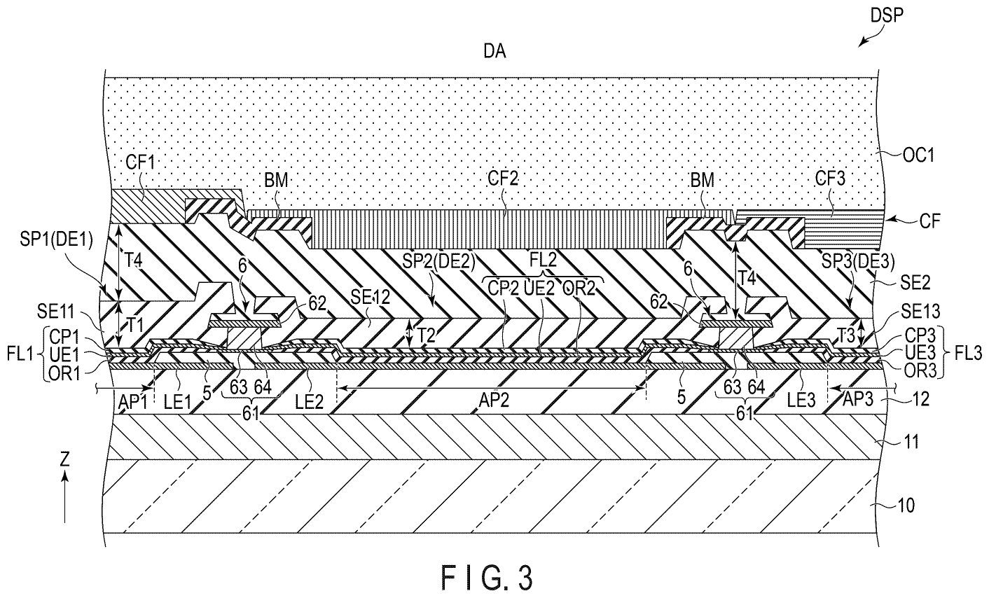

FIG. 3 is a schematic cross-sectional view of the display device DSP according to the first embodiment along line III-III of FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film, which planarizes irregularities formed by the circuit layer 11.

The lower electrodes LE1, LE2, and LE3 are located above the substrate 10 and provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the section in FIG. 3, the lower electrodes LE1, LE2, and LE3 are connected to the respective pixel circuits 1 (the drain electrode of the drive transistor 3 shown in FIG. 1) of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has the width greater than that of the lower portion 61. This configuration allows the both end portions of the upper portion 62 to protrude relative to the side surfaces of the lower portion 61. This shape of the partition 6 is called an overhang shape.

In the example of FIG. 3, the lower portion 61 has a bottom layer 63 provided on the rib layer 5 and a stem layer 64 provided on the bottom layer 63. For example, the bottom layer 63 is formed to be thinner than the stem layer 64. In the example of FIG. 3, the both end portions of the bottom layer 63 protrude from the side surfaces of the stem layer 64. Further, the both end portions of the bottom layer 63 are located between the end portion of the upper portion 62 and the side surface of the stem layer 64 in plan view. The upper portion 62 is provided on the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the side surface of the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers, which improve the extraction efficiency of light emitted from the organic layers OR1, OR2, and OR3, respectively.

In the following explanation, a multilayer body including the organic layer OR1, the upper electrode UE1, and the cap layer CP1 is called a stacked film FL1, a multilayer body including the organic layer OR2, the upper electrode UE2, and the cap layer CP2 is called a stacked film FL2, and a multilayer body including the organic layer OR3, the upper electrode UE3, and the cap layer CP3 is called a stacked film FL3.

Sealing layers SE11, SE12, and SE13, which respectively cover the stacked films FL1, FL2, and FL3 are respectively provided in the subpixels SP1, SP2, and SP3. The sealing layer SE11 (the first sealing layer) continuously covers the display element DE1 and the partition 6 around the display element DE1. The sealing layer SE12 (the second sealing layer) continuously covers the display element DE2 and the partition 6 around the display element DE2. The sealing layer SE13 (the fourth sealing layer) continuously covers the display element DE3 and the partition 6 around the display element DE3.

In the example of FIG. 3, the sealing layer SE11 located on the partition 6 between the subpixels SP1 and SP2 is spaced apart from the sealing layer SE12 located on this partition 6. The sealing layer SE12 located on the partition 6 between the subpixels SP2 and SP3 is spaced apart from the sealing layer SE13 located on this partition 6. It should be noted that two of the sealing layers SE11, SE12 and SE13 may contact each other above the partition 6.

For example, a gap is formed between the respective sealing layers SE11, SE12, and SE13 and the upper portion 62 of the partition 6. The stacked films FL1, FL2 and FL3 may be provided in at least part of these gaps.

The sealing layers SE11, SE12, and SE13 are covered with the sealing layer SE2 (the third sealing layer). In the example shown in FIG. 3, the sealing layers SE11, SE12, and SE13 are directly covered with the sealing layer SE2. In other words, no layer is interposed between the respective sealing layers SE11, SE12, and SE13 and the sealing layer SE2. The sealing layer SE2 contacts the upper portion 62 between the sealing layers SE11 and SE12 and between the sealing layers SE12 and SE13.

A thickness T1 of the sealing layer SE11 in the Z direction is greater than a thickness T2 of the sealing layer SE12 in the Z direction and a thickness T3 of the sealing layer SE13 in the Z direction (T1>T2, T3). For example, the thickness T1 is between two and three times each of the thickness T2 and the thickness T3. In the example of FIG. 3, the thickness T2 is equal to the thickness T3 (T2=T3). A thickness T4 of the sealing layer SE2 in the Z direction is greater than the thicknesses T1, T2, and T3 (T4>T1, T2, T3). The thickness T1 is calculated based on the difference between the thickness of the sum of the thicknesses of the sealing layers SE11 and SE2 and the distance from the upper surface of the upper portion 62 to the lower surface of a light-shielding layer BM.

A color filter layer CF is provided on the sealing layer SE2. The color filter layer CF has a color filter CF1 (the first color filter) located above the display element DE1, a color filter CF2 (the second color filter) located above the display element DE2, and a color filter CF3 (the third color filter) located above the display element DE3. The color filter CF1 covers the pixel aperture AP1 in plan view. The color filter CF2 covers the pixel aperture AP2 in plan view. The color filter CF3 covers the pixel aperture AP3 in plan view. The color filter layer CF is covered with a resin layer OC1 (the first resin layer).

The color filters CF1, CF2, and CF3 are formed of resin materials in different colors. For example, the color filter CF1 is formed of a green-colored resin material. For example, the color filter CF2 is formed of a red-colored resin material. For example, the color filter CF3 is formed of a blue-colored resin material.

The light-shielding layer BM is provided between the color filter layer CF and the sealing layer SE2. In the example of FIG. 3, the light-shielding layer BM is provided on the sealing layer SE2 and is covered with the color filter CF. The light-shielding layer BM is formed into a grating shape and overlaps the rib layer 5 in plan view. For example, the light-shielding layer BM is formed of a resin material that hardly allows light to pass therethrough.

A cover member such as a polarizer, a protective film, or a cover glass may be further provided above the resin layer OC1. This cover member may be attached to the resin layer OC1 via, for example, an adhesive layer such as an optical clear adhesive (OCA).

The organic insulating layer 12 is formed of an organic insulating material such as polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). For example, the rib layer 5 is formed of a silicon oxynitride, and each of the sealing layers SE11, SE12, SE13, and SE2 is formed of a silicon nitride. The resin layer OC1 is formed of, for example, a resinous material (organic insulating materials) such as an epoxy resin or an acrylic resin.

Each of the lower electrodes LE1, LE2, and LE3 has a reflective layer and a pair of conductive oxide layers respectively covering the upper and lower surfaces of the reflective layer. The reflective layer can be formed of, for example, a metal material having excellent light reflectivity, such as silver. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

For example, each of the bottom layer 63 and the stem layer 64 of the partition 6 is formed of a metal material. For the metal material of the bottom layer 63, for example, molybdenum (Mo), titanium (Ti), a titanium nitride (TiN), a molybdenum-tungsten alloy (MoW), or a molybdenum-niobium alloy (MoNb) can be used. For the metal material of the stem layer 64, for example, aluminum (Al), an aluminum-neodymium alloy (AlNd), an aluminum-yttrium alloy (AlY), or an aluminum-silicon alloy (AlSi) can be used. For example, at least one of the bottom layer 63 and the stem layer 64 may comprise a stacked layer structure in which a plurality of layers are stacked. The stem layer 64 may include a layer formed of an insulating material.

For example, the upper portion 62 of the partition 6 includes a stacked layer structure comprising a lower layer composed of a metal material and a top layer composed of a conductive oxide. For the metal material forming the lower layer, for example, titanium, a titanium nitride, molybdenum, tungsten, a molybdenum-tungsten alloy, or a molybdenum-niobium alloy may be used. For a conductive oxide forming the top layer, for example, ITO or IZO may be used. The upper portion 62 may comprise a single-layer structure of a metal material. The upper portion 62 may further include a layer formed of an insulating material.

Common voltage is applied to the partition 6. This common voltage is applied to each of the upper electrodes UE1, UE2, and UE3 in contact with the side surfaces of the lower portion 61. Pixel voltages according to the video signals of the signal lines SL are applied to the lower electrodes LE1, LE2, and LE3 through the respective pixel circuits 1 provided in the subpixels SP1, SP2, and SP3.

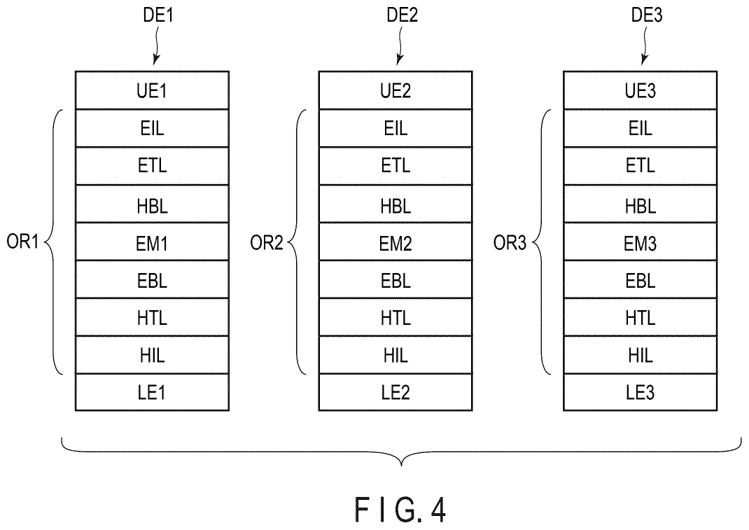

FIG. 4 is a view showing examples of layer structures applicable to the display elements DE1, DE2, and DE3. The following assumes cases where the lower electrodes LE1, LE2, and LE3 correspond to anodes, and the upper electrodes UE1, UE2, and UE3 correspond to cathodes. The organic layers OR1, OR2, and OR3 are configured to emit light in different colors.

The organic layer OR1 comprises a hole injection layer HIL, a hole transport layer HTL, an electron blocking layer EBL, a light emitting layer EM1, a hole blocking layer HBL, an electron transport layer ETL, and an electron injection layer EIL. The hole injection layer HIL is located on the lower electrode LE1. The hole transport layer HTL is located on the hole injection layer HIL. The electron blocking layer EBL is located on the hole transport layer HTL. The light emitting layer EM1 is located on the electron blocking layer EBL. The hole blocking layer HBL is located on the light emitting layer EM1. The electron transport layer ETL is located on the hole blocking layer HBL. The electron injection layer EIL is located on the electron transport layer ETL. The upper electrode UE1 is located on the electron injection layer EIL. The light emitting layer EM1 is formed of a material that emits light in the green wavelength range.

If necessary, the organic layer OR1 may have other function layers, such as a carrier generation layer in addition to the above function layers. Alternatively, the organic layer OR1 may exclude at least one of the above function layers.

In the display element DE2, the organic layer OR2 between the lower electrode LE2 and the upper electrode UE2 comprises a light emitting layer EM2 instead of the light emitting layer EM1. Except this point, the display element DE2 and the display element DE1 have the same configuration. In the display element DE3, the organic layer OR3 between the lower electrode LE3 and the upper electrode UE3 comprises a light emitting layer EM3 instead of the light emitting layer EM1. Except this point, the display element DE3 and the display element DE1 have the same configuration. The light emitting layer EM2 is formed of a material that emits light in the red wavelength range. The light emitting layer EM3 is formed of a material that emits light in the blue wavelength range.

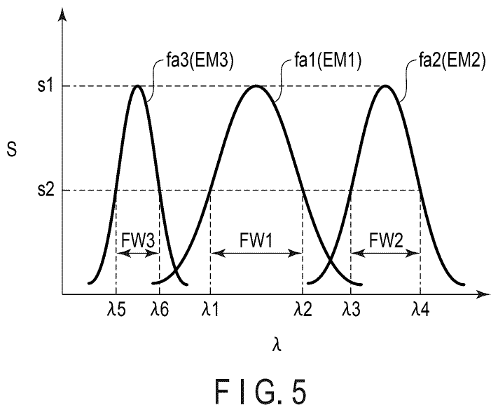

FIG. 5 shows an example of an internal emission spectrum of each of the light emitting layers EM1, EM2, and EM3. A graph in FIG. 5 has a horizontal axis indicative of wavelengths λ and a vertical axis indicative of spectrum strengths S. Curved lines fa1, fa2, and fa3 respectively indicate internal emission spectra of light emitting layers EM1, EM2, and EM3. The internal emission spectrum of each of the light emitting layers EM1, EM2, and EM3 depends on its light emitting material. The internal emission spectrum of each of the light emitting layers EM1, EM2, and EM3 depends on a photo luminescence (PL) spectrum of its light emitting material.

The followings are a comparison of half widths FW1, FW2, and FW3 of the internal emission spectra of the respective light emitting layers EM1, EM2, and EM3. Here, half widths correspond to a width of the wavelength at which the spectrum strength of internal emission spectrum is the half of the maximum value.

In the example shown in FIG. 5, a spectrum strength s1 is the maximum value of the spectrum strengths S of the internal emission spectra of the light emitting layers EM1, EM2, and EM3. In FIG. 5, the light emitting layers EM1, EM2, and EM3 have the same spectrum strength s1; they may have different spectrum strengths s1. A spectrum strength s2 is the half of the spectrum strength s1 (s2=s1/2).

Wavelengths of the internal emission spectra of the light emitting layer EM1 at the spectrum strength s2 are wavelengths λ1 and λ2. Thus, the half width FW1 of the internal emission spectrum of the light emitting layer EM1 corresponds to the difference between the wavelength λ2 and the wavelength λ1 (FW1=λ2−λ1).

Wavelengths of the internal emission spectra of the light emitting layer EM2 at the spectrum strength s2 are wavelengths λ3 and λ4. Thus, the half width FW2 of the internal emission spectrum of the light emitting layer EM2 corresponds to the difference between the wavelength λ4 and the wavelength λ3 (FW2=λ4−λ3).

Wavelengths of the internal emission spectra of the light emitting layer EM3 at the spectrum strength s2 are wavelengths λ5 and λ6. Thus, the half width FW3 of the internal emission spectrum of the light emitting layer EM3 corresponds to the difference between the wavelength λ6 and the wavelength λ5 (FW3=λ6−λ5).

In the example shown in FIG. 5, the half width FW1 is greater than each of the half widths FW2 and FW3 (FW1>FW2, FW3). The half width FW2 is greater than the half width FW3 and is smaller than the half width FW1 (FW1>FW2>FW3). The sizes of the half widths FW1, FW2, and FW3 are not limited to this example. For example, the half widths FW2 and FW3 may be equal to each other.

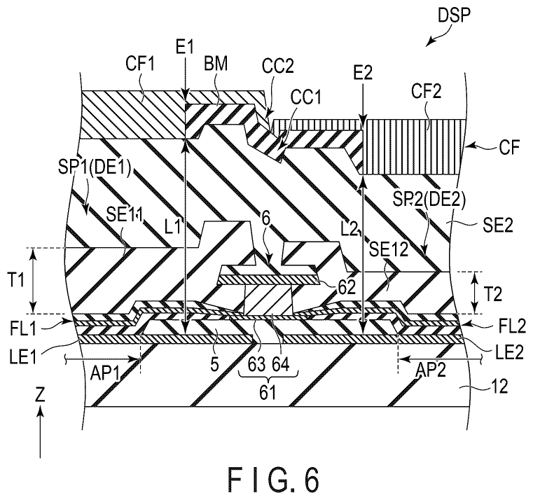

FIG. 6 is a cross-sectional view in which the vicinity of the partition 6 shown in FIG. 3 is enlarged. FIG. 6 omits the illustration of the substrate 10, the circuit layer 11, and the resin layer OC1 shown in FIG. 3.

The light-shielding layer BM has a first end portion E1 and a second end portion E2. The first end portion E1 contacts the color filter CF1. In the example in FIG. 6, the first end portion E1 is covered with the color filter CF1 and contacts the sealing layer SE2. The second end portion E2 contacts the color filter CF2. In the example shown in FIG. 6, the second end portion E2 is covered with the color filter CF2 and contacts the sealing layer SE2. The first end portion E1 and the second end portion E2 overlap the rib layer 5 in plan view. In the example shown in FIG. 6, the first end portion E1 is located between the pixel aperture AP1 and the partition 6 in plan view, and the second end portion E2 is located between the pixel aperture AP2 and the partition 6 in plan view. That is, the first end portion E1 and the second end portion E2 do not overlap the apertures AP1 and AP2 in plan view.

As described above, the thickness T1 of the sealing layer SE11 is greater than the thickness T2 of the sealing layer SE12. Thus, the upper surface of the sealing layer SE2 covering the sealing layers SE11 and SE12 has an uneven height. Due to this uneven height of the upper surface of the sealing layer SE2, the first end portion E1 and the second end portion E2 of the light-shielding layer BM are located at positions different from each other in the Z direction. As a result, a distance L1, which is the distance between the lower electrode LE1 and the first end portion E1 in the Z direction, is greater than a distance L2, which is the distance between the lower electrode LE2 and the second end portion E2 in the Z direction (L1>L2).

The sealing layer SE2 has a recess portion CC1. The light-shielding layer BM has a recess portion CC2. The recess portions CC1 and CC2 are formed according to a gap between the sealing layer SE11 and the sealing layer SE12 spaced apart from each other on the partition 6. The recess portions CC1 and CC2 are located between the first end portion E1 and the second end portion E2 and directly above the partition 6. In the example shown in FIG. 6, the recess portion CC2 is covered with the color filters CF1 and CF2.

The recess portions CC1 and CC2 are tilted from the sealing layer SE11 side to the sealing layer SE12 side due to the uneven height of the upper surface of the sealing layer SE2. For example, the tilt is around 10 to 20 degrees.

Here, external light made incident on the display area DA from the outside of the display device DSP may be reflected on, for example, the lower electrodes LE1, LE2, and LE3. This may affect the display quality of the display device DSP. The reflection of the external light can be suppressed by enlarging areas of the light-shielding layer BM that cover the display area DA. However, enlarging the area of the light-shielding layer BM may result in blocking light emitted from the display elements DE1, DE2, and DE3 in an oblique direction and thus decreasing viewing angle characteristics.

Further, when the display device DSP is viewed obliquely, colors displayed on the display area DA may be distorted due to light emitting materials of each of the light emitting layers EM1, EM2, and EM3 and thicknesses of function layers. The following details this phenomenon.

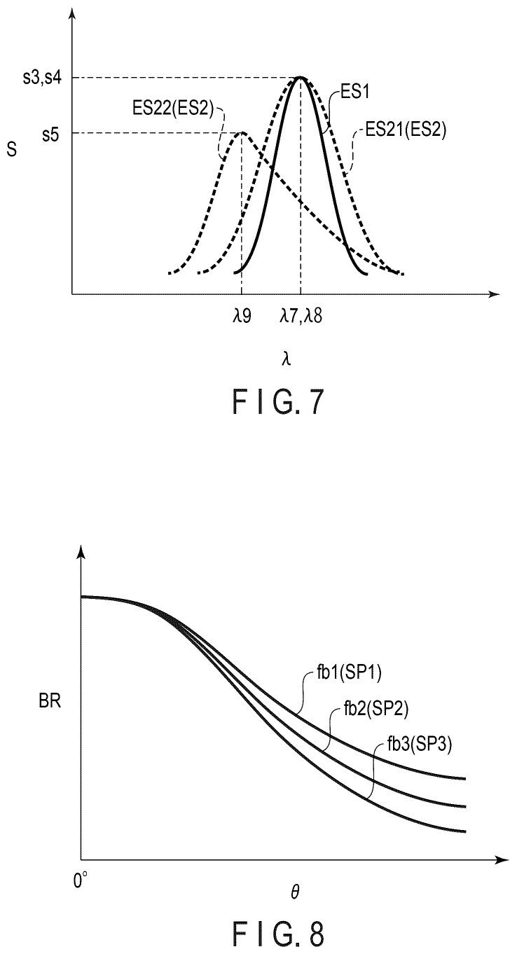

FIG. 7 shows an example of emission spectra. A graph in FIG. 7 has a horizontal axis indicative of wavelengths λ and a vertical axis indicative of spectrum strengths S. For example, FIG. 7 shows green spectra emitted by the light emitting layer EM1 shown in FIG. 4. The emission spectra include an internal emission spectrum ES1 and an interference spectrum ES2. The internal emission spectrum ES1 depends on light emitting materials of the light emitting layer EM1. The interference spectrum ES2 depends on refractive indexes and thicknesses of function layers and cap layers. An interference spectrum ES21 shown in FIG. 7 corresponds to the interference spectrum ES2 in a case where the display device DSP is viewed from the front. An interference spectrum ES22 corresponds to the interference spectrum ES2 in a case where the display device DSP is viewed obliquely.

In the example shown in FIG. 7, a spectrum strength s4, the maximum value of the interference spectrum ES21, is equal to a spectrum strength s3, the maximum value of the internal emission spectrum ES1 (s4=s3). In addition, a wavelength λ8 of the inference spectrum ES21 at the spectrum strength s4 is equal to a wavelength λ7 of the internal emission spectrum ES1 at the spectrum strength s3 (λ8=λ7). On the other hand, a spectrum strength s5, the maximum value of the inference spectrum ES22, is smaller than the spectrum strength s4, the maximum value of the interference spectrum ES21 (s5<s4). In addition, a wavelength λ9 of the interference spectrum ES22 at the spectrum strength s5 is smaller than the wavelength λ8 of the internal emission spectrum ES21 at the spectrum strength s4 (λ9<λ8). That is, when the display device DSP is viewed obliquely, a wavelength λ of the interference spectrum ES2 varies and then the spectrum strength S decreases.

Brightness of light emitted from the display device DSP are affected by wavelengths λ of the internal emission spectrum ES1 and the interference spectrum ES2 and spectrum strengths S. That is, as the display device DSP is viewed more obliquely, the wavelength λ of the interference spectrum ES2 shifts as described above. This decreases the spectrum strength S and thus decreases the brightness. For example, shifting the interference emission spectrum ES21 to the long-wave length direction (the right direction in the figure) can suppress decreases in brightness irrespective of changes in the angles at which the display device DSP is viewed. However, this shifting displaces the wavelength λ7 of the internal emission spectrum ES1 and the wavelength λ8 of the interference spectrum ES21 from each other. This displacement has the risk of reducing the brightness in cases where the display device DSP is viewed from the front.

The above description on the emission spectra of the light emitting layer EM1 applies to the emission spectra of the light emitting layers EM2 and EM3 as well. As shown in FIG. 5, the internal emission spectra of the light emitting layers EM1, EM2, and EM3 are different from one another. Therefore, when the display device DSP is viewed obliquely, the light emitting layers EM1, EM2, and EM3 have different values of: the amount of changes in the wavelengths λ and the spectrum strengths S of the interference spectrum ES2 and brightness of light emitted from the display device DSP.

FIG. 8 is a diagram showing relationships among angles θ and levels of brightness of the respective subpixels SP1, SP2, and SP3. A graph in FIG. 8 has a horizontal axis showing angles θ with respect to the axis parallel to the Z direction and a vertical axis showing levels of brightness BR in cases where the display device DSP is viewed at these angles. Curved lines fb1, fb2, and fb3 indicate respective levels of brightness of the subpixels SP1, SP2, and SP3 at a given angle. The angle θ at the origin indicates 0 degrees. As shown in FIG. 8, the subpixels SP1, SP2, and SP3 have essentially the same brightness when the angle θ is 0 degrees.

As described with reference to FIG. 5, the half width FW2 of the internal emission spectrum of the light emitting layer EM2 is greater than the half width FW3 of the internal emission spectrum of the light emitting layer EM3 and is smaller than the half width FW1 of the internal emission spectrum of the light emitting layer EM1 (FW1>FW2>FW3). As the angle θ increases, the maximum spectrum strength s5, the maximum strength of the inference spectrum ES22, and the wavelength λ9 of the interference spectrum ES22 shown in FIG. 7 decrease. Thus, as the angle θ increases, the brightness BR of the subpixel SP3 attenuates more sharply than the levels of brightness BR of the subpixel SP1 and the subpixel SP2 do. The brightness BR of the subpixel SP1 attenuates more gradually than the levels of brightness BR of the subpixels SP2 and SP3 do. Except 0 degrees, at any given angle θ, the brightness BR of the subpixel SP2 is greater than the brightness BR of the subpixel SP3 and is smaller than the brightness BR of the subpixel SP1 (the brightness BR of the subpixel SP1>the brightness BR of the subpixel SP2>the brightness BR of the subpixel SP3). Thus, as the display device DSP is viewed more obliquely, the color displayed on the display device DSP changes. This configuration is disadvantageous.

Next, an effect of the present embodiment will be described.

In the present embodiment, the sealing layers SE11, SE12, and SE13 are directly covered with the sealing layer SE2. In other words, no layer is interposed between the respective sealing layers SE11, SE12, and SE13 and the sealing layer SE2. Thus, the distances between respective lower electrodes LE1, LE2, and LE3 and the light-shielding layer BM in the Z direction can be shorten. Thus, light emitted from the display elements DE1, DE2, and DE3 in an oblique direction is blocked less by the light-shielding layer BM. This can suppress decreases in the viewing angle characteristics and can decrease the reflectance of the external light.

In the present embodiment, the thickness T1 of the sealing layer SE11 is greater than the thickness T2 of the sealing layer SE12. Thus, the distance L1 between the lower electrode LE1 and the first end portion E1 of the light-shielding layer BM is greater than the distance L2 between the lower electrode LE2 and the second end portion E2 of the light-shielding layer BM. Thus, light emitted from the display element DE1 in an oblique direction is blocked more by the light-shielding layer BM than light emitted from the display element DE2 in an oblique direction. That is, the brightness BR of the subpixel SP1 greatly decreases when the display device DSP is viewed obliquely. In the graph shown in FIG. 8, the brightness BR of the subpixel SP1 decreases such that the curved line fb1 approach the curved lines fb2 and fb3. This configuration decreases the differences in the levels of brightness BR among the subpixels SP1, SP2, and SP3 at a given angle θ. As a result, colors displayed on the display device DSP less likely to change even angle θ varies. Thus, the display quality of the display device DSP can be increased.

### Second Embodiment

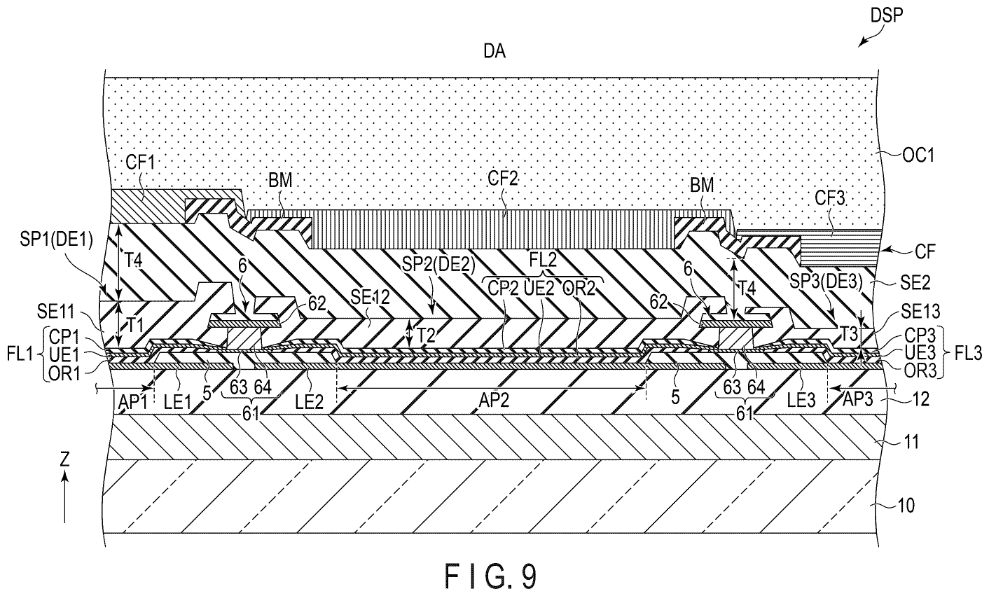

Next, a display device DSP according to the second embodiment will be described. FIG. 9 is a schematic cross-sectional view of the display device DSP according to the second embodiment. The same elements as those of the first embodiment are denoted by the same reference numbers and overlapping descriptions of these elements are omitted.

In the second embodiment, a thickness T2 of a sealing layer SE12 in the Z direction is smaller than a thickness T1 of a sealing layer SE11 in the Z direction and is greater than a thickness T3 of a sealing layer SE13 in the Z direction (T1>T2>T3). Thus, the sealing layers SE11, SE12, and SE13 in the second embodiment have different thicknesses.

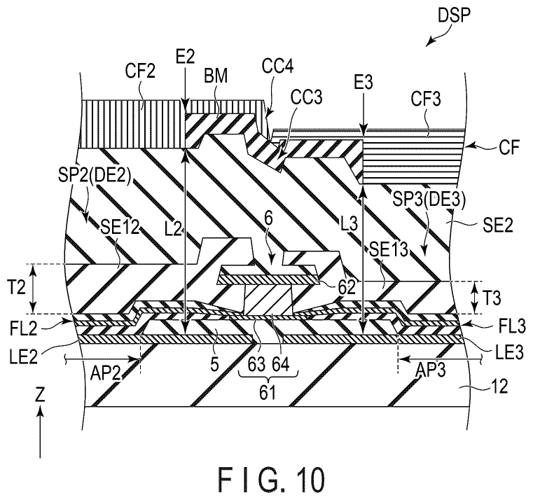

FIG. 10 is a cross-sectional view in which a partition 6 shown in FIG. 9 is enlarged. A light-shielding layer BM has a third end portion E3. A third end portion E3 contacts a color filter CF3. In the example shown in FIG. 10, the third end portion E3 is covered with a color filter CF3 and contacts a sealing layer SE2. The third end portion E3 overlaps a rib layer 5 in plan view. In the example shown in FIG. 10, the third end portion E3 is located between a pixel aperture AP3 and the partition 6 in plan view. That is, the third end portion E3 does not overlap the pixel aperture AP3 in plan view.

The thickness T2 is greater than the thickness T3. Thus, the upper surface of the sealing layer SE2 covering the sealing layers SE12 and SE13 has an uneven height. Due to this uneven height of the upper surface of the sealing layer SE2, the second end portion E2 and the third end portion E3 of the light-shielding layer BM are located at positions different from each other in the Z direction. As a result, a distance L2, which is the distance between a lower electrode LE2 and the second end portion E2 in the Z direction, is greater than a distance L3, which is the distance between a lower electrode LE3 and the third end portion E3 in the Z direction (L2>L3).

The sealing layer SE2 has a recess portion CC3. The light-shielding layer BM has a recess portion CC4. The recess portions CC3 and CC4 are formed according to a gap between the sealing layer SE12 and the sealing layer SE13 spaced apart from each other on the partition 6. The recess portions CC3 and CC4 are located between the second end portion E2 and the third end portion E3 and directly above the partition 6. In the example shown in FIG. 10, the recess portion CC4 is covered with color filters CF2 and CF3.

In the present embodiment, the thickness T1 of the sealing layer SE11 is greater than the thickness T2 of the sealing layer SE12, and the thickness T2 is greater than the thickness T3 of the sealing layer SE13. Thus, the distance L1 between the lower electrode LE1 and the first end portion E1 is greater than the distance L2 between the lower electrode LE2 and the second end portion E2, and the distance L2 is greater than the distance L3 between the lower electrode LE2 and the third end portion E3. Thus, light emitted from the display element DE1 in an oblique direction is blocked more by the light-shielding layer BM than light emitted from the display element DE2 in an oblique direction, and light emitted from the display element DE2 in an oblique direction is blocked more by the light-shielding layer BM than light emitted from the display element DE3 in an oblique direction. In the graph shown in FIG. 8, the brightness BR of each of subpixels SP1 and SP2 decreases such that curved lines fb1 and fb2 approach a curved line fb3. This configuration further decreases the differences in levels of the brightness BR among the subpixels SP1, SP2, and SP3 at a given angle θ than the first embodiment. As a result, colors displayed on the display device DSP is less likely to change even angle θ varies. Thus, the display quality of the display device DSP can be further increased.

### Third Embodiment

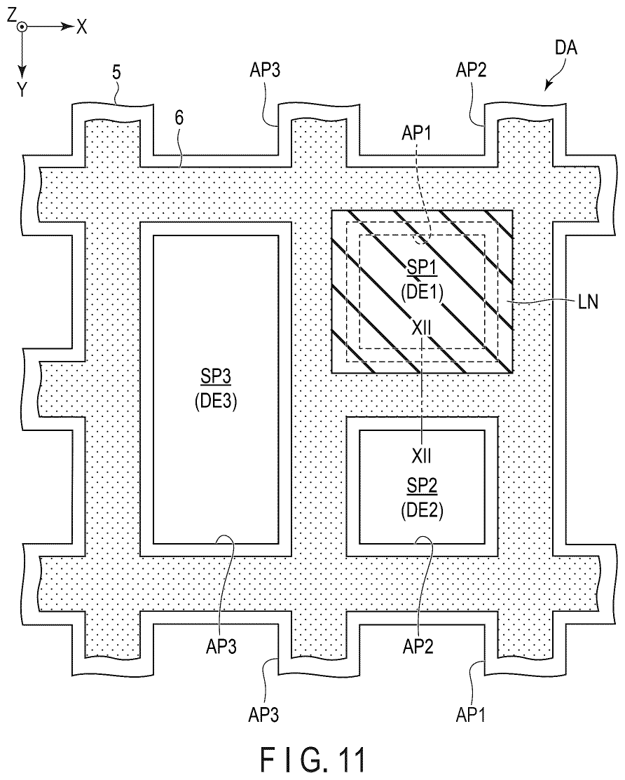

Next, a display device DSP according to the third embodiment will be described. FIG. 11 is a schematic plan view of a display device DSP according to the third embodiment. The same elements as those of the embodiments are denoted by the same reference numbers and overlapping descriptions of these elements are omitted.

The display device DSP further comprises a lens LN covering a pixel aperture AP1. In the example shown in FIG. 11, the peripheral portion of the lens LN overlaps a rib layer 5 and a partition 6 in plan view. In the illustrated example, the shape of the lens LN is a rectangle in plan view. It should be noted that the shape of the lens LN in plan view is not limited to a rectangle and may be another shape such as a circle or an oval.

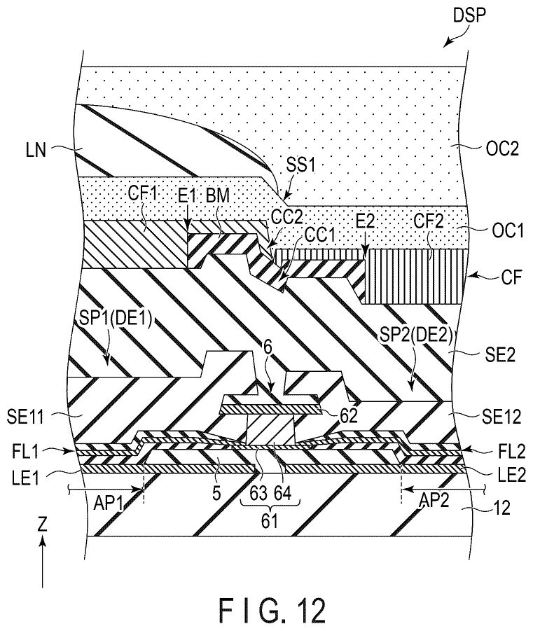

FIG. 12 is a schematic cross-sectional view of the display device DSP according to the third embodiment along line XII-XII of FIG. 11. The lens LN is provided on a resin layer OC1. The lens LN and the resin layer OC1 are directly covered with a resin layer OC2 (the second resin layer). The resin layer OC2 contacts the resin layer OC1 directly above a pixel aperture AP2.

The resin layer OC1 has a tilted plane SS1. The tilt corresponds to differences in thicknesses of sealing layers SE11 and SE12. The tilted surface SS1 is provided above a light-shielding layer BM. In the example shown in FIG. 12, the tilted plane SS1 is located above recess portions CC1 and CC2.

The lens LN covers a first end portion E1 in plan view. The lens LN covers part of each of the recess portions CC1 and CC2 and the tilted plane SS1 in plan view. The lens LN may completely cover each of the recess portions CC1 and CC2 and the tilted plane SS1 in plan view.

The refractive index of the lens LN is different from that of the resin layer OC2. For example, the refractive index of the resin layer OC1 is equal to that of the lens LN, and the refractive index of the lens LN is greater than that of the resin layer OC2. Thus, at the interface between the lens LN and the resin layer OC2, light emitted from a display element DE1 is refracted toward the front direction of the display device DSP. This configuration decreases the brightness BR of a subpixel SP1 in cases where the display device DSP is viewed obliquely and decreases the differences in the levels of brightness BR among subpixels SP1, SP2, and SP3 at a given angle θ. As a result, colors displayed on the display device DSP is less likely to change even angle θ varies. Thus, the display quality of the display device DSP can be further increased.

In the present embodiment, the lens LN does not cover pixel apertures AP2 and AP3. When suppressing light of the subpixels SP2 and SP3 in an oblique direction is desirable, the pixel apertures AP2 and AP3 may be covered with a lens LN different from the lens LN covering the pixel aperture AP1.

All of the display devices that can be implemented by a person of ordinary skill in the art through arbitrary design changes to the display device described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a substrate;
a first lower electrode and a second lower electrode provided above the substrate and spaced apart from each other;
a rib layer having a first pixel aperture overlapping the first lower electrode and a second pixel aperture overlapping the second lower electrode;
a first organic layer contacting the first lower electrode through the first pixel aperture;
a second organic layer contacting the second lower electrode through the second pixel aperture;
a first upper electrode provided on the first organic layer;
a second upper electrode provided on the second organic layer;
a first sealing layer covering the first upper electrode;
a second sealing layer covering the second upper electrode;
a third sealing layer covering the first sealing layer and the second sealing layer;
a first color filter covering the first pixel aperture;
a second color filter covering the second pixel aperture and having a color different from that of the first color filter; and
a light-shielding layer, which has a first end portion contacting the first color filter and a second end portion contacting the second color filter and overlaps the rib layer in plan view, wherein
the first organic layer and the second organic layer are configured to emit light in colors different from each other, and
a distance in a thickness direction of the substrate between the first lower electrode and the first end portion is greater than a distance in the thickness direction between the second lower electrode and the second end portion.

2. The display device of claim 1, wherein
a thickness in the thickness direction of the first sealing layer is greater than a thickness in the thickness direction of the second sealing layer.

3. The display device of claim 1, wherein
the third sealing layer directly covers the first sealing layer and the second sealing layer.

4. The display device of claim 1, wherein
a half width of an internal emission spectrum of a light emitting layer included in the first organic layer is greater than a half width of an internal emission spectrum of a light emitting layer included in the second organic layer.

5. The display device of claim 1, wherein
the first end portion and the second end portion overlap the rib layer in plan view.

6. The display device of claim 1, further comprising:
a partition including a conductive lower portion provided on the rib layer and an upper portion protruding from side surfaces of the lower portion and provided on the lower portion, wherein
the first upper electrode and the second upper electrode contact the lower portion.

7. The display device of claim 6, wherein
the third sealing layer contacts the upper portion.

8. The display device of claim 6, wherein
the light-shielding layer includes a recess portion located between the first end portion and the second end portion and directly above the partition.

9. The display device of claim 6, wherein
the first end portion is located between the first pixel aperture and the partition in plan view, and
the second end portion is located between the second pixel aperture and the partition in plan view.

10. The display device of claim 1, further comprising:
a first resin layer covering the first color filter and the second color filter; and
a lens covering the first pixel aperture and the first end portion and provided on the first resin layer.

11. The display device of claim 10, further comprising:
a second resin layer directly covering the lens and the first resin layer, and
the lens and the second resin layer have different refractive indexes.

12. The display device of claim 10, wherein
the first resin layer has a tilted plane located above the light-shielding layer, and
the lens covers at least part of the tilted plane.

13. The display device of claim 10, further comprising:
a partition including a conductive lower portion provided on the rib layer and an upper portion protruding from side surfaces of the lower portion and provided on the lower portion, wherein
the first upper electrode and the second upper electrode contact the lower portion,
the light-shielding layer includes a recess portion located between the first end portion and the second end portion and directly above the partition, and
the lens covers at least part of the recess portion.

14. The display device of claim 11, wherein
the second resin layer contacts the first resin layer directly above the second pixel aperture.

15. The display device of claim 1, further comprising:
a third lower electrode located above the substrate and spaced apart from the first lower electrode and the second lower electrode;
a third organic layer contacting the third lower electrode;
a third upper electrode provided on the third organic layer;
a fourth sealing layer covering the third upper electrode and covered with the third sealing layer; and
a third color filter having a color different from those of the first color filter and the second color filter, wherein
the rib layer further has a third pixel aperture overlapping the third lower electrode,
the third organic layer contacts the third lower electrode through the third pixel aperture,
the third color filter covers the third pixel aperture,
the light-shielding layer further has a third end portion contacting the third color filter,
the third organic layer is configured to emit light in a color different from those of the first organic layer and the second organic layer, and
a distance in the thickness direction between the second lower electrode and the second end portion is greater than a distance in the thickness direction between the third lower electrode and the third end portion.

16. The display device of claim 15, wherein
a thickness in the thickness direction of the second sealing layer is smaller than a thickness in the thickness direction of the first sealing layer and is greater than a thickness in the thickness direction of the fourth sealing layer.

17. The display device of claim 15, wherein
a half width of an internal emission spectrum of a light emitting layer included in the second organic layer is smaller than a half width of an internal emission spectrum of a light emitting layer included in the first organic layer and is greater than a half width of an internal emission spectrum of a light emitting layer included in the third organic layer.

18. The display device of claim 15, wherein
the first end portion, the second end portion, and the third end portion overlap the rib layer in plan view.

19. The display device of claim 15, further comprising:
a partition including a conductive lower portion provided on the rib layer and an upper portion protruding from side surfaces of the lower portion and provided on the lower portion, wherein
the first upper electrode, the second upper electrode, and the third upper electrode contact the lower portion.

20. The display device of claim 19, wherein
the first end portion is located between the first pixel aperture and the partition in plan view,
the second end portion is located between the second pixel aperture and the partition in plan view, and
the third end portion is located between the third pixel aperture and the partition in plan view.
